(19) United States
(12) Patent Application Publication
(10) Pub. No.: US 2025/0380431 A1
(43) Pub. Date: Dec. 11, 2025

(54) HIGH-BANDWIDTH THREE-DIMENSIONAL STACKED MEMORY WITH A BASE DIE ENABLING COMPUTE LOGIC WITHOUT MEMORY POWER GRID RESTRICTIONS

(71) Applicant: QUALCOMM Incorporated, San Diego, CA (US)

(72) Inventors: Mustafa BADAROGLU, San Diego, CA (US); Zhongze WANG, San Diego, CA (US); Woo Tag KANG, San Diego, CA (US); Jihong CHOI, San Diego, CA (US); Hyun LEE, San Diego, CA (US); Giridhar NALLAPATI, San Diego, CA (US); Periannan CHIDAMBARAM, San Diego, CA (US)

(21) Appl. No.: 18/900,247

(22) Filed: Sep. 27, 2024

Related U.S. Application Data
(60) Provisional application No. 63/657,356, filed on Jun. 7, 2024.

(51) Int. Cl. H10B 80/00; H01L 25/00; H01L 25/065; H01L 25/18

(52) U.S. Cl. CPC H10B 80/00; H01L 25/0657; H01L 25/18; H01L 25/50; H01L 2225/0651; H01L 2225/06513; H01L 2225/06541; H01L 2225/06589

(57) ABSTRACT

A three-dimensional (3D) stacked memory package is described. The 3D stacked memory package includes a base die. The 3D stacked memory package also includes memory dies stacked on the base die. The 3D stacked memory package further includes a package substrate supporting the base die. The 3D stacked memory package also includes a power distribution network (PDN) die on the memory dies stacked on the base die. The 3D stacked memory package further includes a set of wire-bonds coupled between the package substrate and the PDN die to power the memory dies.

### CROSS-REFERENCE TO RELATED APPLICATION

The present application claims the benefit of U.S. Provisional Patent Application No. 63/657,356, filed Jun. 7, 2024, and titled “HIGH-BANDWIDTH THREE-DIMENSIONAL STACKED MEMORY WITH A BASE DIE ENABLING COMPUTE LOGIC WITHOUT MEMORY POWER GRID RESTRICTIONS,” the disclosure of which is expressly incorporated by reference in its entirety.

### BACKGROUND

### Field

Aspects of the present disclosure relate to semiconductor devices and, more particularly, to a high-bandwidth three-dimensional (3D) stacked memory with a base die enabling compute logic without memory power grid restrictions.

### Background

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workloads. A semiconductor memory device solution for providing a high-capacity, low-latency, and high-bandwidth memory is a goal for system designers.

Semiconductor memory devices include, for example, static random-access memory (SRAM) and dynamic random-access memory (DRAM). In practice, memory intensive applications (e.g., artificial intelligence (AI)) consume extensive amounts of DRAM. State of the art high-bandwidth memory (HBM) DRAM provides advantages in performance and power for memory-demanding workloads such as generative-AI. In practice, an HBM DRAM stack is supported by a base die. Unfortunately, significant restrictions on the base die complicate the formation of a custom compute die for enhancing the capabilities of the HBM DRAM stack. Feedthrough power rail (e.g., Vdd-Vss) connections through the base die to the stacked DRAM supported by the base die create blockages in the layout of the base die and involve a change in the logic compute die every time a DRAM technology/vendor changes. Additionally, hot thermal logic below the 3D stacked DRAM limits the performance of the compute die due to thermal limits of DRAM operation.

### SUMMARY

A three-dimensional (3D) stacked memory package is described. The 3D stacked memory package includes a base die. The 3D stacked memory package also includes memory dies stacked on the base die. The 3D stacked memory package further includes a package substrate supporting the base die. The 3D stacked memory package also includes a power distribution network (PDN) die on the memory dies stacked on the base die. The 3D stacked memory package further includes a set of wire-bonds coupled between the package substrate and the PDN die to power the memory dies.

A method of forming a three-dimensional (3D) stacked memory package is described. The method includes stacking a plurality of memory dies on a base die supported by a package substrate. The method also includes stacking a power distribution network (PDN) die on the plurality of memory dies stacked on the base die. The method further includes forming wire-bonds between the PDN die and the package substrate to power the plurality of memory dies.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a high-bandwidth three-dimensional (3D) stacked memory having a base die configured with compute logic and without memory power grid restrictions, in accordance with various aspects of the present disclosure.

FIGS. 2A and 2B illustrate perspective and layout views, respectively, of a high-bandwidth three-dimensional (3D) stacked memory package having a base die configured with compute logic and without memory power grid restrictions, according to various aspects of the present disclosure.

FIGS. 3A to 3K illustrate a process of forming the high-bandwidth three-dimensional (3D) stacked memory package of FIG. 2A, according to various aspects of the present disclosure.

FIG. 4 is a process flow diagram illustrating a method for forming a high-bandwidth three-dimensional (3D) stacked memory package, according to various aspects of the present disclosure.

FIG. 5 is a block diagram showing an exemplary wireless communications system in which a configuration of the disclosure may be advantageously employed.

FIG. 6 is a block diagram illustrating a design workstation used for circuit, layout, and logic design of a semiconductor component, such as the high-bandwidth three-dimensional (3D) stacked memory package disclosed herein.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to.” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workloads. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). In practice, memory intensive applications (e.g., artificial intelligence (AI)) consume extensive amounts of DRAM. State of the art high-bandwidth memory (HBM) DRAM provides advantages in performance and power for memory-demanding workloads such as generative-AI. In practice, an HBM DRAM stack is supported by a base die. Unfortunately, significant restrictions on the base die complicate the formation of a custom compute die for enhancing the capabilities of the HBM DRAM stack.

Feedthrough power rail (e.g., Vdd-Vss) connections through the base die to a stacked DRAM supported by the base die create blockages in the layout of the base die and involve a change in the logic compute die every time a DRAM technology/vendor changes. Additionally, hot thermal logic below a three-dimensional (3D) stacked DRAM limits the performance of the compute die due to thermal limits of DRAM operation. A high-bandwidth 3D stacked memory with a base die enabling compute logic without memory power grid restrictions is desired.

Various aspects of the present disclosure are directed to a high-bandwidth 3D stacked memory with a base die enabling compute logic without memory power grid restrictions. According to various aspects of the present disclosure, a 3D stacked memory package includes a base die supporting a stack of memory dies, in which feedthrough power rail (e.g., Vdd-Vss) through silicon via (TSV) connections are eliminated from the base die. According to these aspects of the present disclosure, the feedthrough Vdd-Vss connections of the base die are replaced with a power distribution network (PDN) die on the stack of memory dies. The PDN die is coupled to a package substrate via a set of bond wires, in which a power grid of the PDN die powers the stack of memory dies. Additionally, the disclosed high-bandwidth 3D stacked memory innovation enables integration and placement schemes supporting insertion of hot compute logic below a 3D HBM stack for any DRAM vendor/process.

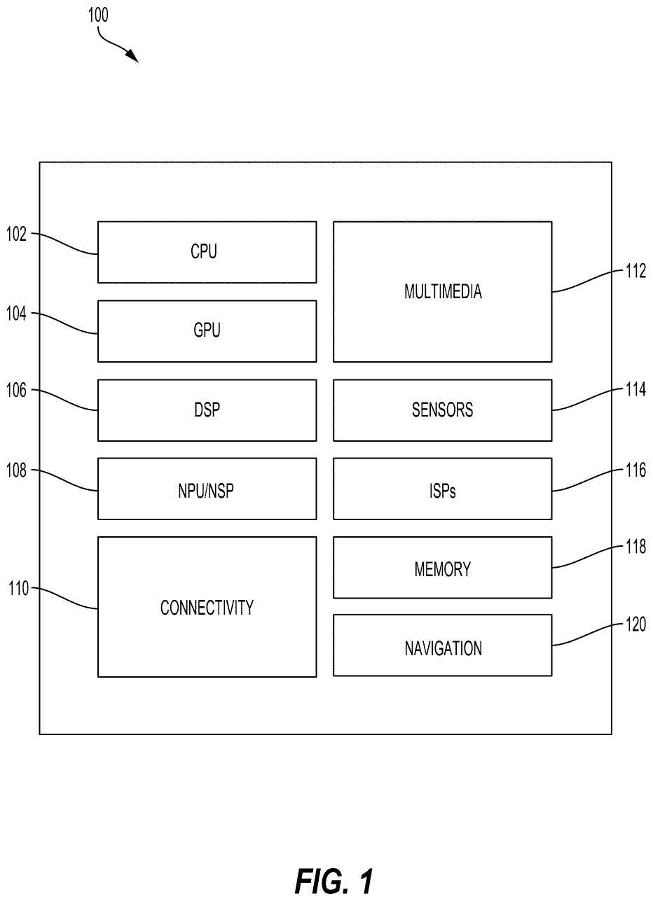

FIG. 1 illustrates an example implementation of a host system-on-chip (SoC) 100, which includes a high-bandwidth three-dimensional (3D) stacked memory having a base die configured with compute logic and without memory power grid restrictions, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

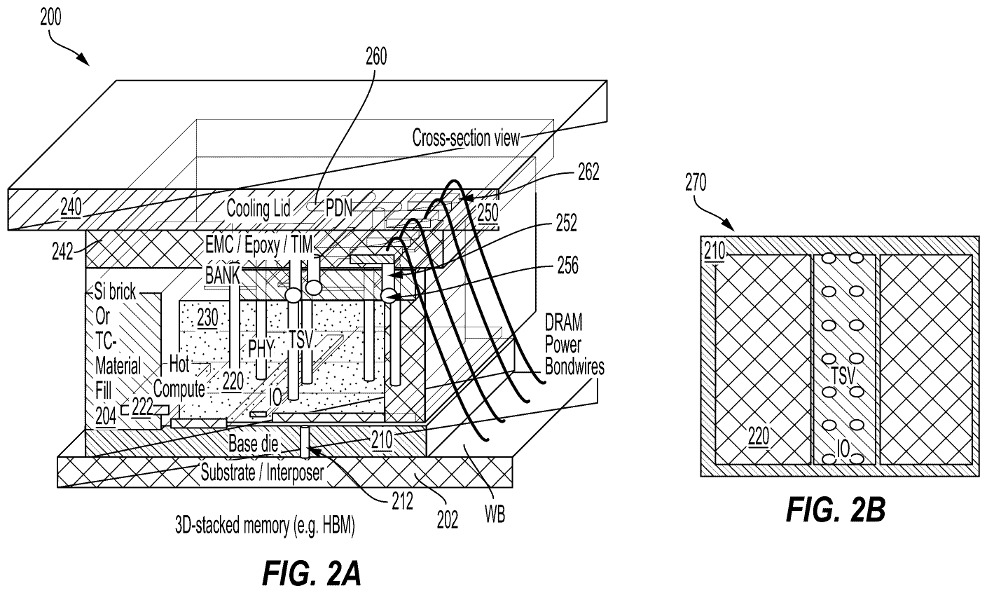

State of the art high-bandwidth memory (HBM) dynamic random-access memory (DRAM) provides advantages in performance and power for memory-demanding workloads such as generative-AI. In practice, an HBM DRAM stack is supported by a base die. Unfortunately, significant restrictions on the base die complicate the formation of a custom compute die for enhancing the capabilities of the HBM DRAM stack. Feedthrough power rail (e.g., Vdd-Vss) connections through the base die to a stacked DRAM supported by the base die create blockages in the layout of the base die and involve a change in the logic compute die every time a DRAM technology/vendor changes. Additionally, hot thermal logic below a 3D stacked DRAM limits the performance of the compute die due to thermal limits of DRAM operation. A high-bandwidth 3D stacked memory with a base die enabling compute logic without memory power grid restrictions is illustrated, for example, in FIGS. 2A and 2B.

FIGS. 2A and 2B illustrate perspective and layout views, respectively, of a high-bandwidth 3D stacked memory package having a base die configured with compute logic and without memory power grid restrictions, according to various aspects of the present disclosure. As shown in FIG. 2A, a high-bandwidth 3D stacked memory package 200 includes a base die 210 (e.g., a first die) that is supported by a package substrate/interposer 202. In various aspects of the present disclosure, the base die 210 supports stacking of memory dies 230 (e.g., dynamic random-access memory (DRAM) dies) on the base die 210. In this example, the memory dies 230 are arranged using a back-to-face stacking of the DRAM dies on the base die 210. In some implementations, the base die 210 supports a stack of memory dies 230 (e.g., a stack of twelve (12) DRAM dies). The number of memory dies stacked on the base die 210 varies in different implementations.

In various aspects of the present disclosure, the memory dies 230 include memory banks (BANK) and an input/output (IO) block that utilize signal through silicon vias (e.g., signal TSVs) extending through the memory dies 230 (e.g., second die) and landing on the base die 210. As shown in FIG. 2A, the signal TSVs provide signal transmission between the memory dies 230 and a physical layer (PHY) 220 of the base die 210. Additionally, the base die 210 includes a logic/signal TSV 212 to provide communication between the PHY 220 as well as a hot compute logic 222 (e.g., CPU/GPU/NPU) and the package substrate/interposer 202.

According to various aspects of the present disclosure, feedthrough power rail (e.g., Vdd-Vss) through silicon via (TSV) connections powering the memory dies 230 are removed from the base die 210 and are replaced by a power distribution network (PDN) die 250 (e.g., a semiconductor die). In various aspects of the present disclosure, the PDN die 250 includes a power grid 260 (e.g., power distribution network (PDN)) composed of a two-dimensional (2D) mesh of back-end-of-line (BEOL) interconnect layers coupled to bond pads 262 on an exterior surface of the PDN die 250 and feedthrough TSVs 252 of the PDN die 250.

In some implementations, the PDN die 250 is arranged face-up (e.g., back-to- back) on the memory dies 230, with the power grid 260 formed on the face of the PDN die 250. Additionally, the PDN die 250 may be configured for contacting decoupling capacitance and power management blocks for better power integrity, according to desired implementations. In this example, the TSVs remaining in the memory dies 230 ensure a uniform power grid to the memory dies 230 stacked below, with relying on additional TSVs in the base die 210 to power the memory dies 230. Elimination of additional TSVs in the base die 210 to power the memory dies 230 beneficially provides additionally flexibility to work with any memory die (e.g., DRAM) vendor.

In this example, the PDN die 250 further includes micro-bumps coupled between the feedthrough TSVs 252 and power TSVs extending through the memory dies 230. Additionally, a set of wire-bonds (WB) is coupled between the bond pads 262 on the exterior surface of the PDN die 250 and the package substrate/interposer 202. The wire-bonds WB may be composed of gold (Au) or other like conductive material. In various implementations, the PDN die 250 is stacked on at least a portion of a top of the memory dies 230, in which a bank of the top of the memory dies 230 is exposed due to a reduced size of the PDN die 250 relative to the memory dies 230. In other implementations, the PDN die 250 is sized to match the memory dies 230. Although illustrated on one side of the PDN die 250, it should be recognized that the wire-bonds WB may be connected from all four sides of PDN die 250.

According to various aspects of the present disclosure, the wire-bonds WB are coupled to the power TSVs extending through the memory dies 230 to power the memory dies 230 through the power grid 260, the feedthrough TSVs 252, and micro-bumps 256 of the PDN die 250 on the top of the memory dies 230. In other implementations, the wire-bonds WB are coupled to the power TSVs extending through the memory dies 230 to power the memory dies 230 through the power grid 260 and the feedthrough TSVs 252 of the PDN die 250 using hybrid-bonding in place of the micro-bumps 256. In some implementations, a length (e.g., <0.5 millimeters) of the wire-bonds WB is selected to avoid voltage droop.

Although described with reference to feedthrough power rail (e.g., Vdd-Vss) TSV connections in the base die 210, it should be recognized that aspects of the present disclosure are applicable to any connection that is not used by the base die 210 and that is needed by the memory dies 230. For example, this shared signal could be connected by bond wire from a top of the memory dies 230, such as a shared control signal including, but not limited to a clock signal, a chip select signal, a test data/control feedthrough power rail (e.g., Vdd-Vss) TSV connections, an address signal, or other like shared control signal. Conventionally, the noted signals are not shared across the memory dies 230; however, in some implementations these signals can be shared across the memory dies 230, for example, the same clock signal can be used by any memory die in the 3D stack of the memory dies 230.

FIG. 2B illustrates a layout view 270 of the base die 210, where the feedthrough power rail (e.g., Vdd-Vss) TSV connections are eliminated in the base die 210, according to various aspects of the present disclosure. Elimination of the feedthrough power rail (e.g., Vdd-Vss) TSV connections in the base die 210 simplifies the logic layout and significantly reduces the area overhead consumed by the DRAM power TSVs. Conventional feedthrough power rail (e.g., Vdd-Vss) TSV connections present a considerable number of obstacles to flexibly design blocks on the base die 210 because the feedthrough power rail TSV connections spread across an area defined by a shadow of the stack of memory dies 230.

In practice, feedthrough TSVs increase the cost of the base die 210 due to the area consumed by both signal TSVs and power TSVs (e.g., ˜1K-2K signal TSVs versus ˜10K-20K power TSVs) in the base die 210. Additionally, significant thermal block restrictions on the base die 210 complicate placement of hot compute cores on the base die 210. In various aspects of the present disclosure, the significant thermal block restrictions on the base die 210 are alleviated by forming a semiconductor brick (e.g., semiconductor block or a silicon (Si) block) and/or thermally conductive (TC) die fill material 204 on the base die 210, as shown in FIG. 2A.

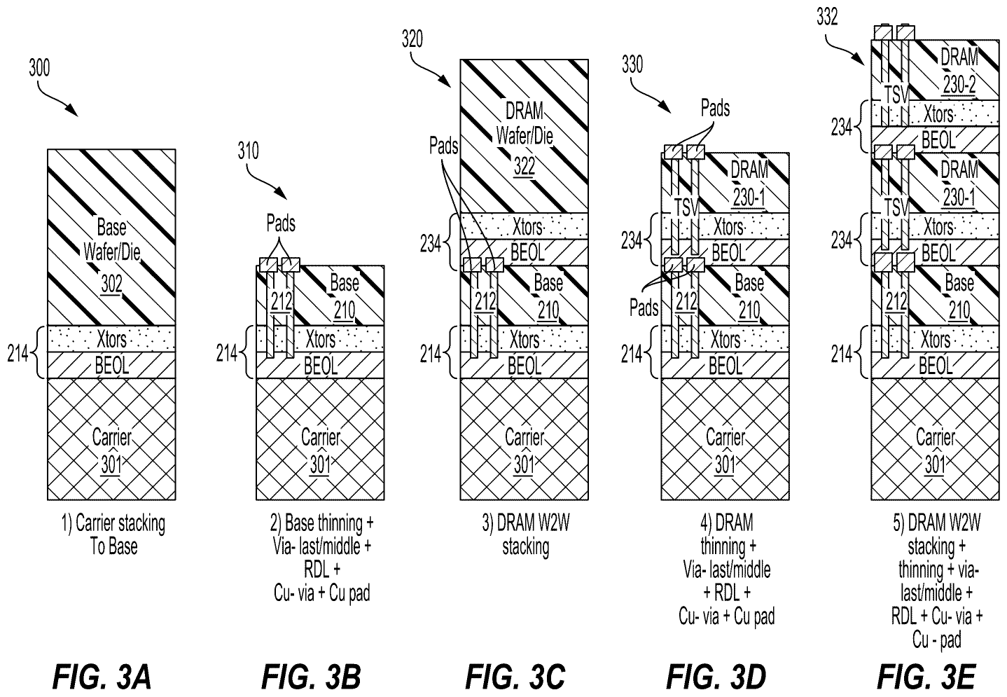

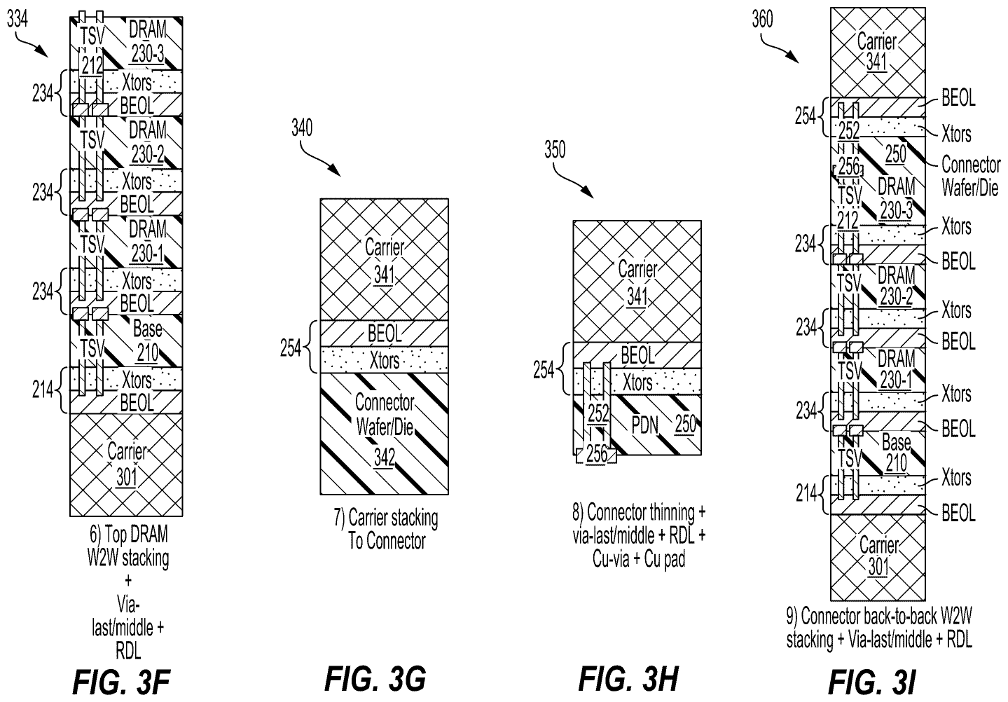

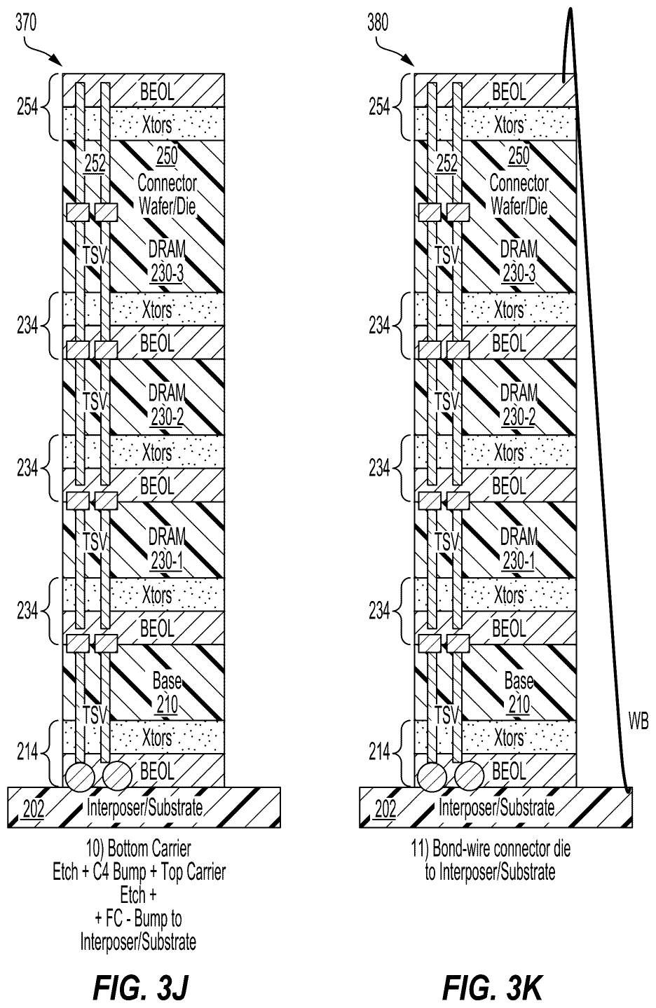

According to various aspects of the present disclosure, the TC die fill material 204 enables placement of the hot compute logic 222 (e.g., CPU/hot logic blocks) on the base die 210. As shown in FIG. 2A, the TC die fill material 204 enhances heat dissipation to a cooling lid 240 coupled to the TC die fill material 204 through a thermal interface material (TIM) 242 (e.g., embedded molding compound (EMC), epoxy, or other like TIM). Additionally, the TIM 242 protects the wire-bonds WB coupled to the memory banks. The TC die fill material 204 may be implemented using an EMC composed of a thermally conductive material (TCM), an oxide, an underfill material (e.g., UF), a non-conductive film (NCF), and/or a spin-on underfill for micro-bump implementations. A process of forming a high-bandwidth 3D stacked memory package is illustrated, for example, in FIGS. 3A to 3K.

FIGS. 3A to 3K illustrate a process of forming the high-bandwidth three-dimensional (3D) stacked memory package 200 of FIG. 2A, according to various aspects of the present disclosure. The process of forming the high-bandwidth 3D stacked memory package 200 of FIG. 2A begins in FIG. 3A.

FIG. 3A illustrates a first step 300 in the process of forming the high-bandwidth 3D stacked memory package 200 of FIG. 2A, according to various aspects of the present disclosure. At the first step 300, a base wafer/die 302 is stacked face-down on a carrier wafer 301. In this example, the base wafer/die 302 includes an active layer 214 having a front-end-of-line (FEOL) layer, including transistors (Xtors), and a back-end-of-line (BEOL) layer on the FEOL layer.

FIG. 3B illustrates a second step 310 in the process of forming the high-bandwidth 3D stacked memory package 200 of FIG. 2A, according to various aspects of the present disclosure. At the second step 310, the base wafer/die 302 of FIG. 3A is thinned to form the base die 210, face-down on the carrier wafer 301. In this example, a via-last/via-middle and redistribution layer (RDL) process forms the logic/signal TSV 212 through the base die 210 and into the BEOL layer of the active layer 214 of the base die 210. In this example conductive pads (e.g., copper (Cu)) are contacted to the logic/signal TSV 212.

FIG. 3C illustrates a third step 320 in the process of forming the high-bandwidth 3D stacked memory package 200 of FIG. 2A, according to various aspects of the present disclosure. At the third step 320, a DRAM wafer/die 322 is stacked through wafer-to-wafer (W2W) stacking on the base die 210. In this example, the DRAM wafer/die 322 includes an active layer 234 having an FEOL layer, including transistors (Xtors), and a BEOL layer on the FEOL layer.

FIG. 3D illustrates a fourth step 330 in the process of forming the high-bandwidth 3D stacked memory package 200 of FIG. 2A, according to various aspects of the present disclosure. At the fourth step 330, the DRAM wafer/die 322 of FIG. 3C is thinned to form a first memory die 230-1, face-down on the base die 210. In this example, a via-last/via-middle and RDL process forms a logic/signal TSV 212 through the first memory die 230-1, the FEOL layer, and into the BEOL layer of the active layer 234 of the first memory die 230-1. In this example conductive pads (e.g., copper (Cu)) are contacted to the logic/signal TSV 212 of the first memory die 230-1.

FIG. 3E illustrates a fifth step 332 in the process of forming the high-bandwidth 3D stacked memory package 200 of FIG. 2A, according to various aspects of the present disclosure. At the fifth step 332, a DRAM wafer/die is stacked through W2W stacking on the first memory die 230-1 and thinned to form a second memory die 230-2, face-down on the first memory die 230-1. In this example, the via-last/via-middle and RDL process forms a logic/signal TSV 212 through the second memory die 230-2, the FEOL layer, and into the BEOL layer of the active layer 234 of the second memory die 230-2. Additionally, conductive pads (e.g., copper (Cu)) are contacted to the logic/signal TSV 212 of the second memory die 230-2.

FIG. 3F illustrates a sixth step 334 in the process of forming the high-bandwidth 3D stacked memory package 200 of FIG. 2A, according to various aspects of the present disclosure. At the sixth step 334, a DRAM wafer/die is stacked through W2W stacking on the second memory die 230-2 and thinned to form a third memory die 230-3 (e.g., top DRAM die), face-down on the second memory die 230-2. In this example, the via-last/via-middle and RDL process forms a logic/signal TSV 212 through the third memory die 230-3, the FEOL layer, and into the BEOL layer of the active layer 234 of the third memory die 230-3.

FIG. 3G illustrates a seventh step 340 in the process of forming the high-bandwidth 3D stacked memory package 200 of FIG. 2A, according to various aspects of the present disclosure. At the seventh step 340, a carrier wafer 341 is stacked face-down on a connector wafer/die 342. In this example, the connector wafer/die 342 includes an active layer 254 having a FEOL layer (e.g., Xtors) and a BEOL layer on the FEOL layer.

FIG. 3H illustrates an eighth step 350 in the process of forming the high-bandwidth 3D stacked memory package 200 of FIG. 2A, according to various aspects of the present disclosure. At the eighth step 350, the connector wafer/die 342 of FIG. 3G is thinned to form the PDN die 250. In this example, a via-last/via-middle and RDL process forms the feedthrough TSVs 252 through the PDN die 250, the FEOL layer, and into the BEOL layer of the active layer 254 of the PDN die 250. In this example, micro-bumps 256 are contacted to the feedthrough TSVs 252.

FIG. 3I illustrates a ninth step 360 in the process of forming the high-bandwidth 3D stacked memory package 200 of FIG. 2A, according to various aspects of the present disclosure. At the ninth step 360, the PDN die 250 is stacked through back-to-back W2W stacking on the third memory die 230-3 to couple the feedthrough TSVs 252 to the logic/signal TSV 212 of the third memory die 230-3 through the micro-bumps 256. In some implementations, the PDN die 250 is arranged face-up (e.g., back-to-back) on the memory dies 230, with the power grid 260 formed on the face of the PDN die 250 using, for example, the BEOL layer of the active layer 254 of the PDN die 250.

FIG. 3J illustrates a tenth step 370 in the process of forming the high-bandwidth 3D stacked memory package 200 of FIG. 2A, according to various aspects of the present disclosure. At the tenth step 370, the carrier wafer 301 of FIG. 3I is etched to expose the active layer 214 of the base die 210, and the connector wafer/die 342 of FIG. 3G is etched to expose the active layer 214 of the base die 210 and package bumps are formed and contacted to the signal TSV of the third memory die 230-3. Additionally, package bumps (flip-chip (FC)-bumps) are formed and contacted to the signal TSV of the base die 210 to the package substrate/interposer 202.

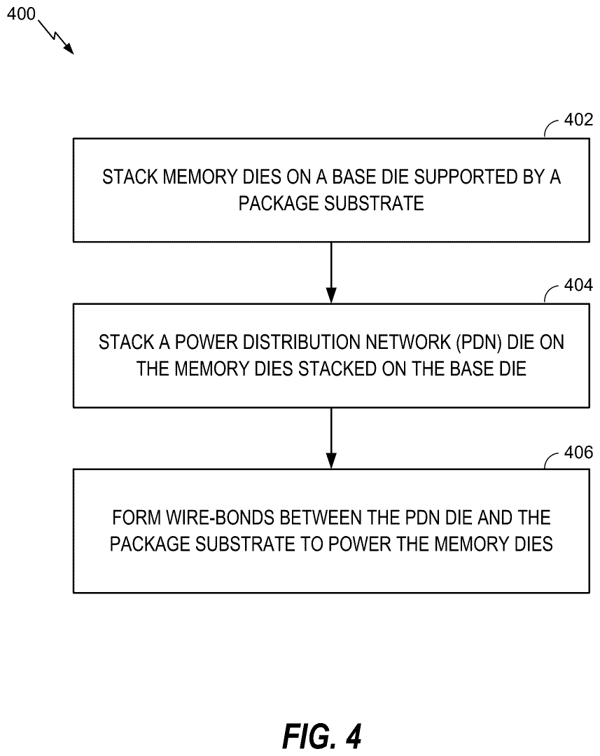

FIG. 3K illustrates an eleventh step 380 in the process of forming the high-bandwidth 3D stacked memory package 200 of FIG. 2A, according to various aspects of the present disclosure. At the eleventh step 380, wire-bonds (WB) are formed between the PDN die 250 and the package substrate/interposer 202. In some implementations, a length (e.g., <0.5 millimeters) of the wire-bonds WB is selected to avoid voltage droop. A process flow for forming a high-bandwidth 3D stacked memory package is illustrated, for example, in FIG. 4.

FIG. 4 is a process flow diagram illustrating a method 400 for forming a high-bandwidth three-dimensional (3D) stacked memory package, according to various aspects of the present disclosure. The method 400 begins at block 402, in which memory dies are stacked on a base die supported by a package substrate. For example, as shown in FIG. 2A, the base die 210 supports stacking of memory dies 230 (e.g., dynamic random-access memory (DRAM) dies) on the base die 210. In this example, the memory dies 230 are arranged using a back-to-face stacking of the DRAM dies on the base die 210. In some implementations, the base die 210 supports a stack of memory dies 230 (e.g., a stack of twelve (12) DRAM dies). The number of memory dies stacked on the base die 210 varies in different implementations.

At block 404, a power distribution network (PDN) die is stacked on the memory dies stacked on the base die. For example, as shown in FIG. 2A, feedthrough power rail (e.g., Vdd-Vss) through silicon via (TSV) connections powering the memory dies 230 are removed from the base die 210 and are replaced by a power distribution network (PDN) die 250. In various aspects of the present disclosure, the PDN die 250 includes a power grid 260 composed of a 2D mesh of back-end-of-line (BEOL) interconnect layers coupled to bond pads 262 on an exterior surface of the PDN die 250 and feedthrough TSVs 252 of the PDN die 250.

At block 406, wire-bonds are formed between the PDN die and the package substrate to power the memory dies. For example, as shown in FIG. 2A, a set of wire-bonds (WB) is coupled between the bond pads 262 on the exterior surface of the PDN die 250 and the package substrate/interposer 202. The wire-bonds WB may be composed of gold (Au) or other like conductive material. In this example, the wire-bonds WB are coupled to the power TSVs extending through the memory dies 230 to power the memory dies 230 through the power grid 260, the feedthrough TSVs 252 and the micro-bumps 256 of the PDN die 250 on the top of the memory dies 230.

Various aspects of the present disclosure employ an integration solution that minimizes and eliminates the feedthrough power rail (e.g., Vdd-Vss) connections to a 3D dynamic random-access memory (DRAM) stack by eliminating through silicon vias (TSVs) in a base die support of the DRAM stack. The disclosed high-bandwidth 3D stacked memory innovation enables integration and placement schemes supporting inserting of hot compute logic below a 3D high-bandwidth memory (HBM) stack for any DRAM vendor/process. Various aspects of the present disclosure eliminate DRAM power TSVs on a base die by providing the power through wire-bonds enabling a reduced size base die and less restrictions on block physical design. Additionally, these aspects of the present disclosure integrate a semiconductor (e.g., silicon (Si)) brick enabling placement of hot compute logic on a base die. In various aspects of the present disclosure, a PDN die isolates DRAM power bond wires from a top DRAM tier integrated together with logic power TSVs, logic signal TSVs, logic-DRAM interface signals (e.g., uBump/hybrid bonding), and feedthrough signal TSVs.

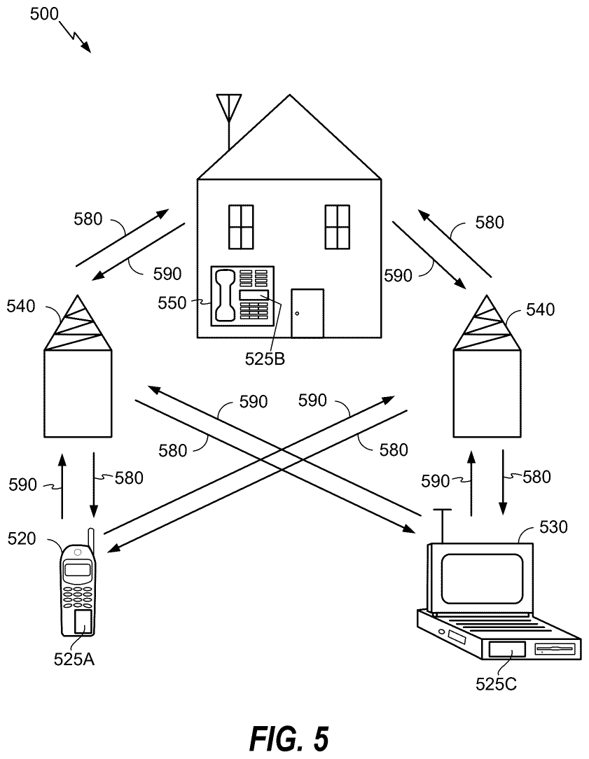

FIG. 5 is a block diagram showing an exemplary wireless communications system 500 in which a configuration of the disclosure may be advantageously employed. For purposes of illustration, FIG. 5 shows three remote units 520, 530, and 550, and two base stations 540. It will be recognized that wireless communications systems may have many more remote units and base stations. Remote units 520, 530, and 550 include integrated circuit (IC) devices 525A, 525C, and 525B that include the disclosed high-bandwidth 3D stacked memory package. It will be recognized that other devices may also include the disclosed high-bandwidth 3D stacked memory package, such as the base stations, switching devices, and network equipment. FIG. 5 shows forward link signals 580 from the base stations 540 to the remote units 520, 530, and 550, and reverse link signals 590 from the remote units 520, 530, and 550 to the base stations 540.

In FIG. 5, remote unit 520 is shown as a mobile telephone, remote unit 530 is shown as a portable computer, and remote unit 550 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 5 illustrates remote units according to aspects of the present disclosure, the disclosure is not limited to these exemplary illustrated units. Aspects of the present disclosure may be suitably employed in many devices, which include the disclosed high-bandwidth 3D stacked memory package.

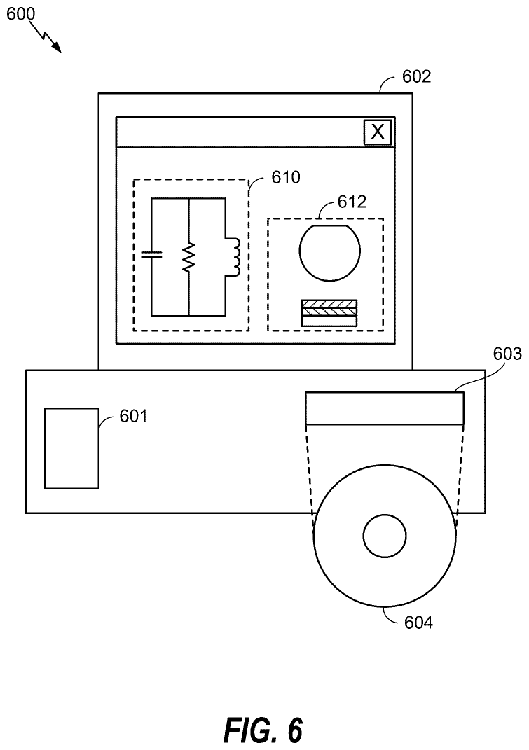

FIG. 6 is a block diagram illustrating a design workstation used for circuit, layout, and logic design of a semiconductor component, such as the high-bandwidth three-dimensional (3D) stacked memory package disclosed above. A design workstation 600 includes a hard disk 601 containing operating system software, support files, and design software such as Cadence or OrCAD. The design workstation 600 also includes a display 602 to facilitate design of a circuit 610 or an integrated circuit (IC) component 612, such as a high-bandwidth 3D stacked memory package. A storage medium 604 is provided for tangibly storing the design of the circuit 610 or the IC component 612 (e.g., the high-bandwidth 3D stacked memory package). The design of the circuit 610 or the IC component 612 may be stored on the storage medium 604 in a file format such as GDSII or GERBER. The storage medium 604 may be a CD-ROM, DVD, hard disk, flash memory, or other appropriate device. Furthermore, the design workstation 600 includes a drive apparatus 603 for accepting input from or writing output to the storage medium 604.

Data recorded on the storage medium 604 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 604 facilitates the design of the circuit 610 or the IC component 612 by decreasing the number of processes for designing semiconductor wafers.

Implementation examples are described in the following numbered clauses:
1. A three-dimensional (3D) stacked memory package, comprising:
a base die;
a plurality of memory dies stacked on the base die;
a package substrate supporting the base die;
a power distribution network (PDN) die on the plurality of memory dies stacked on the base die; and
a set of wire-bonds coupled between the package substrate and the PDN die to power the plurality of memory dies.

2. The 3D stacked memory package of clause 1, in which the PDN die further comprises bond pads coupled between the set of wire-bonds and the PDN die.
3. The 3D stacked memory package of clause 2, in which the PDN die comprises:
a power grid coupled to the bond pads; and
feedthrough through silicon vias (TSVs) coupled to the power grid and extending through the PDN die.
4. The 3D stacked memory package of clause 3, further comprising micro-bumps coupled between the feedthrough TSVs and power TSVs extending through the plurality of memory dies.
5. The 3D stacked memory package of any of clauses 1-4, wherein the base die comprises hot compute logic.
6. The 3D stacked memory package of any of clauses 1-5, further comprising a thermally conductive (TC) die fill material on the base die.
7. The 3D stacked memory package of clause 6, further comprising a thermal interface material (TIM) on the TC die fill material and one of the plurality of memory dies stacked on the base die.
8. The 3D stacked memory package of clause 7, further comprising a cooling lid on the TIM.
9. The 3D stacked memory package of any of clauses 1-8, further comprising a semiconductor brick on the base die.
10. The 3D stacked memory package of any of clauses 1-9, further comprising a plurality of signal through silicon vias (TSVs) extending between the plurality of memory dies and landing on the base die.
11. A method of forming a three-dimensional (3D) stacked memory package, the method comprising:
stacking a plurality of memory dies on a base die supported by a package substrate;
stacking a power distribution network (PDN) die on the plurality of memory dies stacked on the base die; and
forming wire-bonds between the PDN die and the package substrate to power the plurality of memory dies.
12. The method of clause 11, in which stacking the PDN die further comprises forming bond pads coupled between the wire-bonds and the PDN die.
13. The method of clause 12, further comprises: forming a power grid coupled to the bond pads; and forming feedthrough through silicon vias (TSVs) coupled to the power grid and extending through the PDN die.
14. The method of clause 13, further comprising forming micro-bumps coupled between the feedthrough TSVs and power TSVs extending through the plurality of memory dies.
15. The method of any of clauses 11-14, wherein the base die comprises hot compute logic.
16. The method of any of clauses 11-15, further comprising forming a thermally conductive (TC) die fill material on the base die.
17. The method of clause 16, further comprising forming a thermal interface material (TIM) on the TC die fill material and one of the plurality of memory dies stacked on the base die.
18. The method of clause 17, further comprising forming a cooling lid on the TIM.
19. The method of any of clauses 11-18, further comprising forming a semiconductor brick on the base die.
20. The method of any of clauses 11-19, further comprising forming a plurality of signal through silicon vias (TSVs) extending between the plurality of memory dies and landing on the base die.

For a firmware and/or software implementation, the methodologies may be implemented with modules (e.g., procedures, functions, etc.) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A three-dimensional (3D) stacked memory package, comprising:
a base die;
a plurality of memory dies stacked on the base die;
a package substrate supporting the base die;
a power distribution network (PDN) die on the plurality of memory dies stacked on the base die; and
a set of wire-bonds coupled between the package substrate and the PDN die to power the plurality of memory dies.

2. The 3D stacked memory package of claim 1, in which the PDN die further comprises bond pads coupled between the set of wire-bonds and the PDN die.

3. The 3D stacked memory package of claim 2, in which the PDN die comprises:
a power grid coupled to the bond pads; and
feedthrough through silicon vias (TSVs) coupled to the power grid and extending through the PDN die.

4. The 3D stacked memory package of claim 3, further comprising micro-bumps coupled between the feedthrough TSVs and power TSVs extending through the plurality of memory dies.

5. The 3D stacked memory package of claim 1, wherein the base die comprises hot compute logic.

6. The 3D stacked memory package of claim 1, further comprising a thermally conductive (TC) die fill material on the base die.

7. The 3D stacked memory package of claim 6, further comprising a thermal interface material (TIM) on the TC die fill material and one of the plurality of memory dies stacked on the base die.

8. The 3D stacked memory package of claim 7, further comprising a cooling lid on the TIM.

9. The 3D stacked memory package of claim 1, further comprising a semiconductor brick on the base die.

10. The 3D stacked memory package of claim 1, further comprising a plurality of signal through silicon vias (TSVs) extending between the plurality of memory dies and landing on the base die.

11. A method of forming a three-dimensional (3D) stacked memory package, the method comprising:
stacking a plurality of memory dies on a base die supported by a package substrate;
stacking a power distribution network (PDN) die on the plurality of memory dies stacked on the base die; and
forming wire-bonds between the PDN die and the package substrate to power the plurality of memory dies.

12. The method of claim 11, in which stacking the PDN die further comprises forming bond pads coupled between the wire-bonds and the PDN die.

13. The method of claim 12, further comprises:
forming a power grid coupled to the bond pads; and
forming feedthrough through silicon vias (TSVs) coupled to the power grid and extending through the PDN die.

14. The method of claim 13, further comprising forming micro-bumps coupled between the feedthrough TSVs and power TSVs extending through the plurality of memory dies.

15. The method of claim 11, wherein the base die comprises hot compute logic.

16. The method of claim 11, further comprising forming a thermally conductive (TC) die fill material on the base die.

17. The method of claim 16, further comprising forming a thermal interface material (TIM) on the TC die fill material and one of the plurality of memory dies stacked on the base die.

18. The method of claim 17, further comprising forming a cooling lid on the TIM.

19. The method of claim 11, further comprising forming a semiconductor brick on the base die.

20. The method of claim 11, further comprising forming a plurality of signal through silicon vias (TSVs) extending between the plurality of memory dies and landing on the base die.
